(19) United States
(12) Patent Application Publication
(10) Pub. No.: US 2008/0166835 A1
(43) Pub. Date: Jul. 10, 2008

(54) Method of bonding a solder ball and a base plate and method of manufacturing packaging structure of using the same

(75) Inventors: Yee-Wen Yen, Keelung City (TW); Hong-Yao Wei, Danshuei Township (TW); Wei-Kai Liou, Banciao City (TW); Chien-Chung Jao, Taipei City (TW); Chia-Pyng Lee, Danshuei Township (TW)

Correspondence Address: BACON & THOMAS, PLLC, 625 SLATERS LANE, FOURTH FLOOR, ALEXANDRIA, VA, 22314, US

(73) Assignee: National Taiwan University of Science and Technology, Taipei (TW)

(21) Appl. No.: 11/783,471

(22) Filed: Apr. 10, 2007

(30) Foreign Application Priority Data
Jan. 5, 2007 (TW) 96100580

(51) Int. Cl. H01L 21/00; H01L 21/44

(52) U.S. Cl. 438/107; 438/612; 257/E21.476; 257/E21.001

(57) ABSTRACT

A method of bonding a solder ball and a base plate and a method of manufacturing a packaging structure using the same are provided. The method of bonding a solder ball and a base plate includes the following steps. First, a base plate including an electrode layer and a base material layer is provided. The electrode layer is disposed on the base material layer. Next, a barrier layer is formed on the electrode layer. Then, a metal layer is formed on the barrier layer. The thickness of the metal layer is about 10˜18 micrometers. Further, a solder ball is disposed on the metal layer. Afterwards, the solder ball, the metal layer, the barrier layer and the electrode layer are heated to a reacting temperature and kept for a holding time.

This application claims the benefit of Taiwan application Serial No. 96100580, filed Jan. 5, 2007, the subject matter of which is incorporated herein by reference.

### BACKGROUND OF THE INVENTION

1. Field of the Invention

The invention relates in general to a method of bonding a solder ball and a base plate and a method of manufacturing a packaging structure using the same, and more particularly to a method of bonding a solder ball and a base plate and a method of manufacturing a packaging structure using the same applied in an lead-free manufacturing process.

2. Description of the Related Art

As electronic products are gaining greater and greater popularity in the market, the manufacturers are devoted to the development of multi-functional products to meet the increasing market demands. As electronic products are capable of performing more and more functions, the number of electronic parts is increased at the same time. Therefore, how to effectively integrate various electronic parts onto a substrate has become an important topic in the manufacturing process. Eutectic tin-lead solder is commonly used for soldering electronic parts onto the substrate. However, the lead is a heavy metal, it may not only pollute the environment but also be harmful to human body. Therefore, the manufacturers are devoted to the development of lead-free solder that is more environmental-friendly and that reduces the quantity of lead in the products. Normally, the liquefaction temperature for lead-free solder is about 217° C., which is 40° C. higher than that of conventional tin-lead solder. That is, in a manufacturing process that adopts lead-free solder, the temperature of the manufacturing process is increased, which raises the damage to the substrate and the electronic parts. Consequently, the application of lead-free manufacturing process is limited.

Currently, a method for reducing the liquefaction temperature of lead-free solder is provided. In this method, a metal with low-melting temperature, such as indium or bismuth, is added to the lead-free solder. However, indium is a precious metal, i.e. it is expensive, and the reduction in the liquefaction temperature for lead-free solder requires a large amount of indium; therefore, the method of adding low-melting temperature metal not only increases the cost of manufacturing but also lowers its value of practical applications. Furthermore, the indium residuals left on the soldering surface after bonding process lower the liquefaction temperature between the soldering surfaces. In some cases, the liquefaction temperature between the soldering surfaces may be even lower than the operating temperature of the electronic product, which severely degrades the reliability of the soldering surfaces and further affects the yield rate of the products.

### SUMMARY OF THE INVENTION

The invention is directed to a method of bonding a solder ball and a base plate and a method of manufacturing a packaging structure using the same. The solder ball and the base plate are soldered via a thin metal layer, which is completely consumed after the reaction, such that the invention has the advantages of lowering the reflowing temperature, enhancing the strength of the bonding surface, reducing the material cost, and being compatible with existing manufacturing process.

According to a first aspect of the present invention, a method of bonding a solder ball and a base plate is provided. First, a base plate including an electrode layer and a base material layer is provided. The electrode layer is disposed on the base material layer. Next, a barrier layer is formed on the electrode layer. Then, a metal layer is formed on the barrier layer. The thickness of the metal layer is about 10˜18 micrometers. Further, a solder ball is disposed on the metal layer. Afterwards, the solder ball, the metal layer, the barrier layer and the electrode layer are heated to a reacting temperature and kept for a holding time.

According to a second aspect of the present invention, a method of manufacturing a packaging structure is provided. First, a base plate including a base material layer and an electrode layer is provided. The base material layer has a first surface and a second surface opposite to the first surface, and the electrode layer is disposed on the first surface. Then, a barrier layer is formed on the electrode layer. Next, a metal layer whose thickness is about 10˜18 micrometers is formed on the barrier layer. Further, a chip is provided on the second surface, and the chip and the base plate are wire bonded. Subsequently, a solder ball is disposed on the metal layer. Afterwards, the solder ball, the metal layer, the barrier layer and the electrode layer are heated to a reacting temperature and kept for a holding time.

The invention will become apparent from the following detailed description of the preferred but non-limiting embodiments. The following description is made with reference to the accompanying drawings.

### BRIEF DESCRIPTION OF THE DRAWINGS

FIG. 1A is a perspective of a base plate, a barrier layer and a metal layer according to a first embodiment of the invention;

FIG. 1B is a perspective showing a solder ball disposed on the metal layer in FIG. 1A;

FIG. 1C is a perspective of the solder ball, the metal layer, the barrier layer and the electrode layer in FIG. 1B after heating to a temperature and being kept for a holding time;

FIG. 2A is a perspective of an interface between the solder ball and the barrier layer bonded together at 160° C. and after being kept for 3 minutes;

FIG. 2B is a perspective of an interface between the solder ball and the barrier layer bonded together at 200° C. and after being kept for 3 minutes;

FIG. 3A is a perspective of a base plate, a barrier layer and a metal layer according to a second embodiment of the invention;

FIG. 3B is a perspective showing a chip is provided to a second surface in FIG. 3A;

FIG. 3C is a perspective showing a solder ball disposed on the metal layer in FIG. 3B;

FIG. 3D is a perspective of the solder ball, the metal layer, the barrier layer and the electrode layer in FIG. 3C after heating to a temperature and being kept for a holding time; and

FIG. 4 is a perspective of a packaging structure according to a second embodiment of the invention.

### DETAILED DESCRIPTION OF THE INVENTION

Two embodiments are disclosed for elaborating the invention. However, the invention is not limited thereto. And unnecessary elements are omitted in the embodiments to clearly show the features of the invention.

### First Embodiment

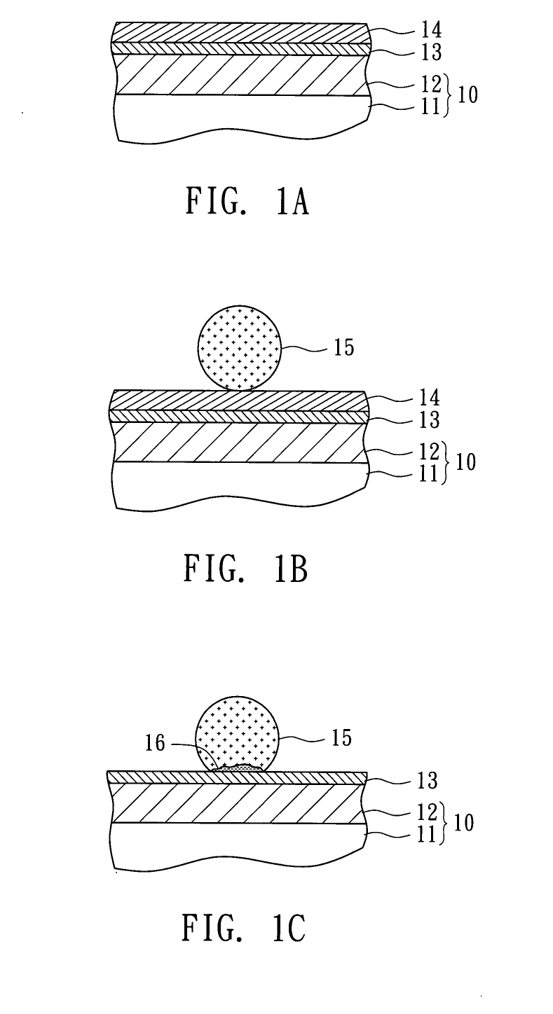

Referring to FIGS. 1A˜1C. FIG. 1A is a perspective of a base plate, a barrier layer and a metal layer according to a first embodiment of the invention. FIG. 1B is a perspective showing a solder ball disposed on the metal layer in FIG. 1A. FIG. 1C is a perspective of the solder ball, the metal layer, the barrier layer and the electrode layer in FIG. 1B after heating to a temperature and being kept for a holding time.

The solder bonding method according to the first embodiment of the invention includes the following steps. First, a base plate 10 including an electrode layer 12 and a base material layer 11 is provided. The electrode layer 12 is disposed on the base material layer 11. Then, a barrier layer 13 and a metal layer 14 are sequentially formed on the electrode layer 12 as indicated in FIG. 1A.

Next, as indicated in FIG. 1B, a solder ball 15 is disposed on the metal layer 14.

Then, the solder ball 15, the metal layer 14, the barrier layer 13 and the electrode layer 12 are heated to a reacting temperature. After that, the reacting temperature is kept for a holding time.

After the above steps of heating and holding the temperature, the metal layer 14 is completely melted with the solder ball 15, and an intermetallic compound 16 is formed between the solder ball 15 and the barrier layer 13 for tightly bonding the solder ball 15 and the base plate 10 together, as indicated in FIG. 1C.

In the present embodiment of the inventon, the solder ball is made from a tin-based lead-free solder composed of Sn-3.0 Ag-0.5 Cu (SAC) or Sn-0.7 Cu (SC). The electrode layer 12 is made from copper or aluminum. The barrier layer 13 is preferably made from nickel and is electroplated onto the electrode layer 12. The thickness of the barrier layer 13 is about 3˜7 micrometers for preventing the solder ball 15 (made from tin for example) from reacting with the electrode layer 12 (made from copper for example). Thus, the bonding strength of the interface between the solder ball 15 and the base plate 10 is further proved. In addition, the metal layer 14 is preferably made from indium and is electroplated onto the barrier layer 13 either. Preferably, the thickness of the metal layer is about 10˜18 micrometers. After the above steps of heating and holding the temperature, the metal layer 14 is substantially consumed completely. The base plate 10 can be exemplified by a large scale integration circuit chip or a packaging substrate of a packaging structure. The large scale integration circuit chip can be flip chip bonded through the bonding method according to the present embodiment of the inventon. The packaging substrate can be exemplified by a packaging substrate in a ball grid array (BGA) packaging structure or a flip chip packaging structure. On the other hand, in the present embodiment of the inventon, the reacting temperature for bonding the solder ball 15 and the base plate 10 is around 160° C.˜200° C., and the holding time is around 3˜5 minutes.

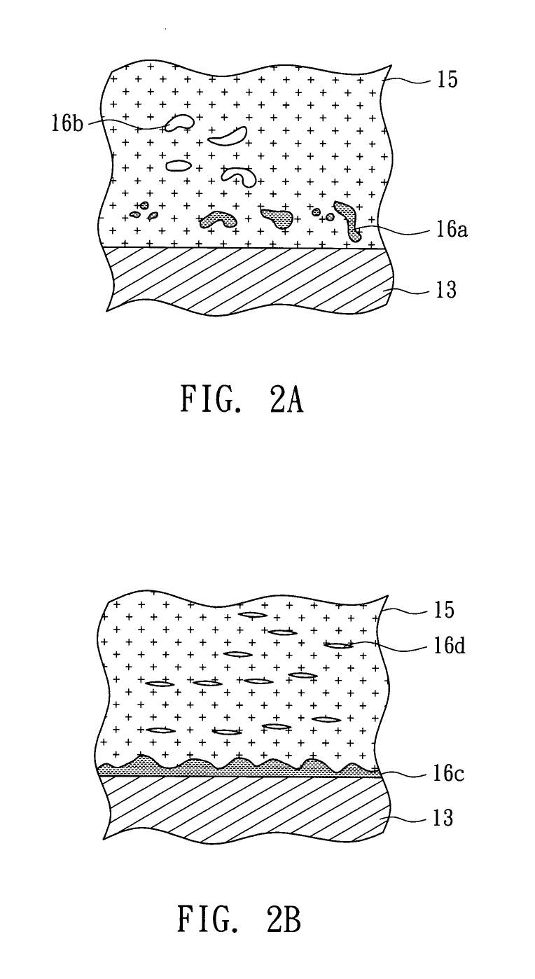

After the solder ball 15 and the base plate 10 are bonded through the method disclosed in the first embodiment of the invention, the state of the reacting interface is analyzed, and one set of the analysis results is disclosed below. The materials of the solder ball 15 is exemplified by Sn-3.0 Ag-0.5 Cu; the barrier layer 13 is exemplified by nickel; the metal layer 14 is exemplified by indium; and the electrode layer 12 is exemplified by copper. Referring to FIG. 2A and drawing attached 1. FIG. 2A is a perspective of an interface between the solder ball and the barrier layer bonded together at 160° C. and after being kept for 3 minutes. Drawing attached 1 is a back-scattering electron image of FIG. 2A. According to the analysis, the metal layer 14 made from indium no more exists between the barrier layer 13 and the solder ball 15, that is, the metal layer 14 is completely consumed. There is a first intermetallic compound 16a made from Cu₆Sn₅ existing at the interface between the solder ball 15 and the barrier layer 13, and the first intermetallic compound 16a is in a peeling-like state. Besides, there is a layer of second intermetallic compound 16b made from AgIn₂ existing above the first intermetallic compound 16a. The shape of the second intermetallic compound 16b is irregular.

Referring to FIG. 2B and drawing attached 2. FIG. 2B is a perspective of an interface between the solder ball and the barrier layer bonded together at 200° C. and after being kept for 3 minutes. Drawing attached 2 is a back-scattering electron image of FIG. 2B. In FIG. 2B and drawing attached 2, the materials of the solder ball 15 is exemplified by Sn-3.0 Ag-0.5 Cu; the barrier layer 13 is exemplified by nickel; the metal layer 14 is exemplified by indium; and the electrode layer 12 is exemplified by copper. According to the analysis, only a third intermetallic compound 16c made from Cu₆Sn₅ exists at the interface between the solder ball 15 and the barrier layer 13, and there exists no peeling-like intermetallic compounds. Further, a fourth intermetallic compound 16d made from Ag₃Sn is found in the solder ball 15, and the metal layer 14 made from indium no more exists between the barrier layer 13 and the solder ball 15.

According to the above analysis results, the metal layer 14 electroplated onto the barrier layer 13 with a thickness of 10˜18 micrometers is completely melted within the solder ball 15 after the metal layer 14, the solder ball 15, the barrier layer 13 and the electrode layer 12 are heated to a reacting temperature of at least 160° C. and than kept for a holding time of 3 minutes. Consequently, a first intermetallic compound 16a, a second intermetallic compound 16b, a third intermetallic compound 16c and a fourth intermetallic compound 16d are formed at the interface between the solder ball 15 and the electrode layer 12. The interface is formed integrally, and the strength of the interface is enhanced. Further, the metal layer 14 made from indium effectively lowers the reflowing temperature of the lead-free solder from about 240° C.˜270° C. to about 160° C.˜200° C.

According to the bonding method disclosed in the first embodiment of the invention for bonding the solder ball 15 and the base plate 10, the solder ball 15 and the base plate 10 are bonded together via a metal layer 14 having a thickness of around 10˜18 micormeters at the conditions that heating to a reacting temperature of around 160° C.˜200° C. and keeping the temperature for a holding time of around 3˜5 minutes. After the steps of heating to and keeping the temmperature, the metal layer 14 is completely consumed, and the barrier layer 13 contacts with the solder ball 15, such that the diffusion of the electrode layer 12 is prohibited, and the reaction between the electrode layer 12 and the solder ball 15 is prevented. Besides that, a level and smooth intermetallic compound 16 is formed at the interface between the solder ball 15 and the base plate 10, such that the strength of the interface is enhanced.

### Second Embodiment

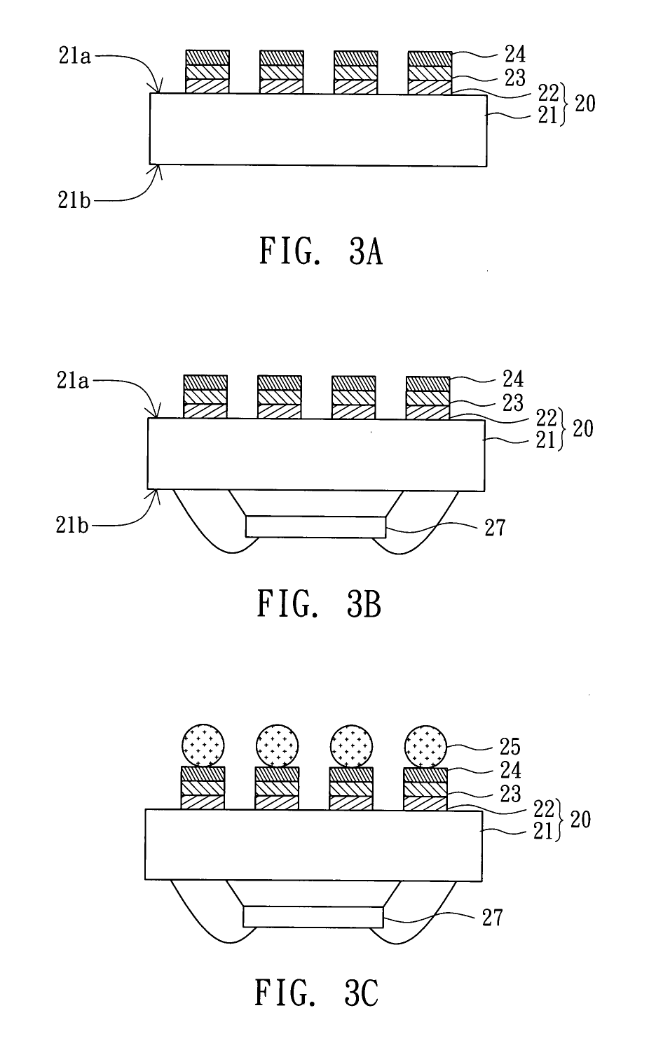

Referring to FIGS. 3A˜3D. FIG. 3A is a perspective of a base plate, a barrier layer and a metal layer according to a second embodiment of the invention. FIG. 3B is a perspective showing a chip is provided to a second surface in FIG. 3A. FIG. 3C is a perspective showing a solder ball disposed on the metal layer in FIG. 3B. FIG. 3D is a perspective of the solder ball, the metal layer, the barrier layer and the electrode layer of FIG. 3C after heating to a temperature and being kept for a holding time.

The method of manufacturing a packaging structure disclosed in the second embodiment of the present invention includes the following steps. First, a base plate 20 including a base material layer 21 and an electrode layer 22 is provided. The base material layer 21 has a first surface 21a and a second surface 21b opposite to the first surface 21a. The electrode layer 22 is disposed on first surface 21a. In the present embodiment, the electrode layer 22 only covers a portion of the first surface 21a. Then, a barrier layer 23 is formed on the electrode layer 22. After that, a metal layer 24 having a thickness of around 10˜18 micrometers is formed on the barrier layer 23, as indicated in FIG. 3A. The metal layer 24 is preferably made from indium and is electroplated onto the barrier layer 23. The barrier layer 23 having a thickness of around 3˜7 micrometers is preferably made from nickel and is also electroplated onto the electrode layer 22. The electrode layer 22 is preferably made from copper.

Then, a chip 27 is disposed on the second surface 21b, and the chip 27 is wire bonded to the base plate 20, as indicated in FIG. 3B.

Next, as indicated in FIG. 3C, a solder ball 25 is disposed on the metal layer 24. The solder ball 25 is a tin-based lead-free solder made from Sn-3.0Ag-0.5Cu or Sn-0.7Cu.

Then, the solder ball 25, the metal layer 24, the barrier layer 23 and the electrode layer 22 are heated to a reacting temperature and kept for a holding time.

After the steps of heating to and keeping the temperature, the metal layer 24 is completely melted within the solder ball 25, and an intermetallic compound 26 is formed between the solder ball 25 and the barrier layer 23 for bonding the solder ball 25 and the base plate 20 closely, as indicated in FIG. 3D.

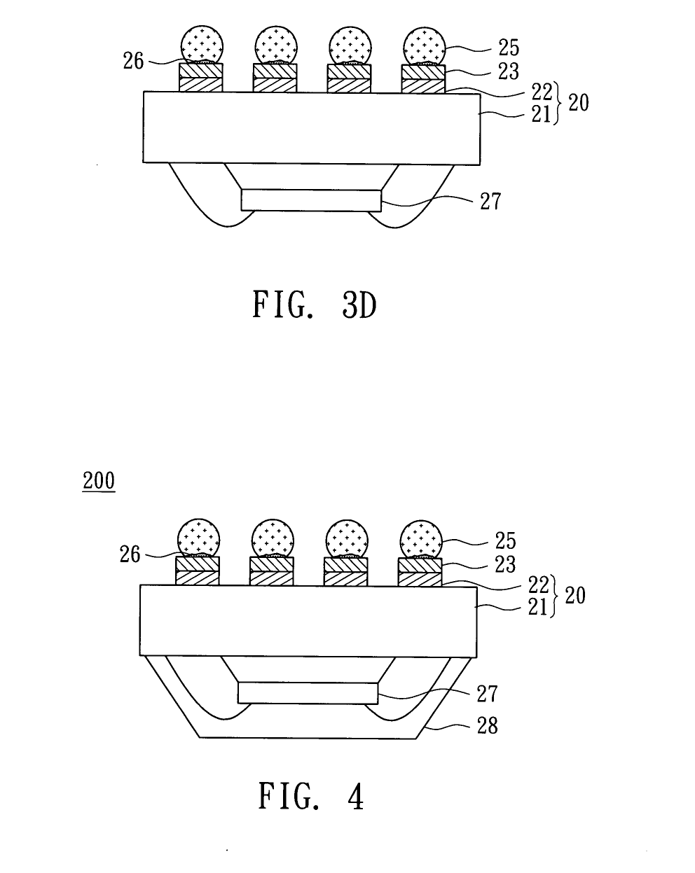

The method of manufacturing a packaging structure disclosed in the present embodiment of the inventon further implements the step of forming a sealant 28 on the second surface 21b. The sealant 28 encapsulates the chip 27. Referring to FIG. 4, a perspective of a packaging structure according to a second embodiment of the invention is shown. After the step of forming the sealant 28, the packaging structure 200 according to the second embodiment of the invention is completed. In the present embodiment of the inventon, the packaging structure 200 is exemplified by a ball grid array (BGA) packaging structure. However, the packaging structure 200 can also be exemplified by a flip chip packaging structure.

According to the method of manufacturing a packaging structure 200 disclosed in the present embodiment of the inventon, the solder ball 25 and the base plate 20 are bonded together via a metal layer 24 having a thickness of around 10˜18 micrometers at the conditions that heating to a reacting temperature of around 160° C.˜200° C. and keeping the temperature for a holding time of around 3˜5 minutes. The metal layer 24 is completely consumed after the steps of heating to and keeping the temmperature. In the present embodiment of the inventon, the metal layer 24 is preferably made from indium, such that the reacting temperature for bonding the solder ball 25 and the base plate 20 is lowered, lest the elements of the packaging structure 200 might be damaged due to high temperature. Besides, a smooth intermetallic compound 26 is formed at the interface between the solder ball 25 and the barrier layer 23, and the reliability of the bonding surface is enhanced.

According to the method of bonding a solder ball and a base plate and the method of manufacturing a packaging structure disclosed in the above preferred embodiments of the present invention, a metal layer with a thickness of 10˜18 micrometers is electroplated onto the barrier layer, and then the solder ball and the base plate are reacted at the conditions that heating to a reacting temperature of around 160° C. ˜200° C. and keeping the temperature for a holding time of around 3 to 5 minutes so as to bond the solder ball and the base plate. After the step of heating to and keeping the temperature, the metal layer is completely consumed, and an intermetallic compound is formed at the interface between the solder ball and the base plate. The invention has the advantages of increasing the strength and reliability of the bonding surface by forming a level and smooth intermetallic compound. In addition, the metal layer made from indium is used such that the bonding method according to the preferred embodiments of the invention can be performed under a lower reacting temperature. Furthermore, because the electroplating thickness of the metal layer is only 10˜18 micrometers, the material cost for the metal layer is reduced. Moreover, the bonding method according to the preferred embodiments of the invention only needs to electroplate the metal layer onto existing base plate, so the bonding method has the virtue of being compatible with existing lead-free manufacturing process.

While the invention has been described by way of example and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of bonding a solder ball and a base plate, comprising:
providing a base plate comprising an electrode layer and a base material layer, wherein the electrode layer is disposed on the base material layer;
forming a barrier layer on the electrode layer;
forming a metal layer on the barrier layer, wherein the thickness of the metal layer is about 10˜18 micrometers;
disposing a solder ball on the metal layer;
heating the solder ball, the metal layer, the barrier layer and the electrode layer to a reacting temperature; and
keeping the reacting temperature for a holding time.

2. The bonding method according to claim 1, wherein the metal layer is made from indium.

3. The bonding method according to claim 2, wherein the metal layer is electroplated onto the barrier layer.

4. The bonding method according to claim 1, wherein the barrier layer is made from nickel.

5. The bonding method according to claim 4, wherein the thickness of the barrier layer is about 3˜7 micrometers.

6. The bonding method according to claim 5, wherein the barrier layer is electroplated onto the electrode layer.

7. The bonding method according to claim 1, wherein the solder ball is made from a tin-based lead-free solder.

8. The bonding method according to claim 7, wherein the solder ball is made from Sn-3.0 Ag-0.5 Cu (SAC) or Sn-0.7 Cu (SC).

9. The bonding method according to claim 1, wherein the reacting temperature is about 160° C. to 200° C.

10. The bonding method according to claim 9, wherein the holding time is about 3 to 5 minutes.

11. The bonding method according to claim 1, wherein the base plate is a large scale integration circuit chip or a packaging substrate.

12. The bonding method according to claim 11, wherein the electrode layer is made from copper or aluminum.

13. The bonding method according to claim 1, wherein after keeping the reacting temperature for the holding time, the metal layer is substantially consumed completely.

14. A method of manufacturing packaging structure, comprising:
providing a base plate comprising a base material layer and an electrode layer, wherein the base material layer has a first surface and a second surface opposite to the first surface, and the electrode layer is disposed on the first surface;
forming a barrier layer on the electrode layer;
forming a metal layer on the barrier layer, wherein the thickness of the metal layer is about 10˜18 micrometers;
providing a chip on the second surface, and wire bonding the chip and the base plate;
disposing a solder ball on the metal layer;
heating the solder ball, the metal layer, the barrier layer and the electrode layer to a reacting temperature; and
keeping the reacting temperature for a holding time.

15. The manufacturing method according to claim 14, wherein the metal layer is made from indium.

16. The manufacturing method according to claim 15, wherein the metal layer is electroplated onto the barrier layer.

17. The manufacturing method according to claim 14, wherein the barrier layer is made from nickel.

18. The manufacturing method according to claim 17, wherein the thickness of the barrier layer is about 3˜7 micrometers.

19. The manufacturing method according to claim 18, wherein the barrier layer is electroplated onto the electrode layer.

20. The manufacturing method according to claim 14, wherein the electrode layer is made from copper.

21. The manufacturing method according to claim 14, wherein the electrode layer covers a portion of the first surface.

22. The manufacturing method according to claim 14, wherein the solder ball is made from a tin-based lead-free solder.

23. The manufacturing method according to claim 22, wherein the solder ball is made from Sn-3.0 Ag-0.5 Cu (SAC) or Sn-0.7 Cu (SC).

24. The manufacturing method according to claim 14, wherein the reacting temperature is about 160° C. to 200° C.

25. The manufacturing method according to claim 24, wherein the holding time is about 3 to 5 minutes.

26. The manufacturing method according to claim 14, wherein after keeping the reacting temperature for the holding time, the metal layer is substantially consumed completely.

27. The manufacturing method according to claim 14, after the step of providing the chip on the second surface, the method further comprises:
forming a sealant on the second surface, wherein the sealant encapsulates the chip.

28. The manufacturing method according to claim 14, wherein the packaging structure is a ball grid array (BGA) packaging structure or a flip chip packaging structure.
